(19) United States
(12) Patent Application Publication
(10) Pub. No.: US 2015/0047085 A1
(43) Pub. Date: Feb. 19, 2015

(54) PREPARATION AND COATING OF PILOT EQUIPMENT WITH ORGANIC PHOTOVOLTAIC FILMS TO PRODUCE ELECTRICITY FOR EMERGENCY POWER SUPPLY SYSTEMS FOR PILOTS

(71) Applicants: John Anthony CONKLIN, Apalachin, NY (US); Scott Ryan HAMMOND, Wheat Ridge, CO (US)

(72) Inventors: John Anthony CONKLIN, Apalachin, NY (US); Scott Ryan HAMMOND, Wheat Ridge, CO (US)

(73) Assignee: NEW ENERGY TECHNOLOGIES, INC., Columbia, MD (US)

(21) Appl. No.: 14/317,966

(22) Filed: Jun. 27, 2014

Related U.S. Application Data
(60) Provisional application No. 61/841,243, filed on Jun. 28, 2013.
(60) Provisional application No. 61/842,355, filed on Jul. 2, 2013.
(60) Provisional application No. 61/841,244, filed on Jun. 28, 2013.
(60) Provisional application No. 61/842,357, filed on Jul. 2, 2013.
(60) Provisional application No. 61/841,247, filed on Jun. 28, 2013.
(60) Provisional application No. 61/842,365, filed on Jul. 2, 2013.
(60) Provisional application No. 61/841,248, filed on Jun. 28, 2013.
(60) Provisional application No. 61/842,372, filed on Jul. 2, 2013.
(60) Provisional application No. 61/842,796, filed on Jul. 3, 2013.
(60) Provisional application No. 61/841,251, filed on Jun. 28, 2013.
(60) Provisional application No. 61/842,375, filed on Jul. 2, 2013.
(60) Provisional application No. 61/842,803, filed on Jul. 3, 2013.

(51) Int. Cl. H01L 31/048; H01L 31/18; H01L 31/05

(52) U.S. Cl. CPC H01L 31/0481; H01L 31/05; H01L 31/1892
USPC 2/2.14; 136/256; 136/244; 156/280; 156/239; 2/410

(57) ABSTRACT

A method for fabricating organic photovoltaic-based electricity-generating military pilot equipment, including flight suits, helmets, helmet visors, and related equipment is described. In particular, a method for fabricating such equipment utilizing lamination of highly flexible organic photovoltaic films is described. High-throughput and low-cost fabrication options also allow for economical production.

### CROSS-REFERENCE TO RELATED APPLICATIONS

This application claims priority under 35 U.S.C. 119(e) of U.S. Provisional Application No. 61/841,243, filed on Jun. 28, 2013 (Attorney Docket No. 7006/0141PRO1), U.S. Provisional Application No. 61/842,355, filed on Jul. 2, 2013 (Attorney Docket No. 7006/0141PR02), U.S. Provisional Application No. 61/841,244, filed on Jun. 28, 2013 (Attorney Docket No. 7006/0142PR01), U.S. Provisional Application No. 61/842,357, filed on Jul. 2, 2013 (Attorney Docket No. 7006/0142PR02), U.S. Provisional Application No. 61/841,247, filed on Jun. 28, 2013 (Attorney Docket No. 7006/0143PR01), U.S. Provisional Application No. 61/842,365, filed on Jul. 2, 2013 (Attorney Docket No. 7006/0143PR02), U.S. Provisional Application No. 61/841,248, filed on Jun. 28, 2013 (Attorney Docket No. 7006/0144PR01), U.S. Provisional Application No. 61/842,372, filed on Jul. 2, 2013 (Attorney Docket No. 7006/0144PR02), U.S. Provisional Application No. 61/842,796, filed on Jul. 3, 2013 (Attorney Docket No. 7006/0145PR01), U.S. Provisional Application No. 61/841,251, filed on Jun. 28, 2013 (Attorney Docket No. 7006/0146PR01), U.S. Provisional Application No. 61/842,375, filed on Jul. 2, 2013 (Attorney Docket No. 7006/0146PR02) and U.S. Provisional Application No. 61/842,803, filed on Jul. 3, 2013 (Attorney Docket No. 7006/0147PR01); the entire contents of all the above identified patent applications are hereby incorporated by reference in their entirety. This application is related to Applicants' co-pending U.S. applications, which are filed concurrently herewith on Jun. 27, 2014, 7006/0141PUS01, 7006/0142PUS01, 7006/0143PUS01, 7006/0144PUS01, 7006/0146PUS01 and 7006/0147PUS01; each of which is incorporated herein by reference in its entirety.

### FIELD OF THE INVENTION

The present invention is directed to the use of organic photovoltaic (OPV) devices—cell, modules, or arrays—as coatings for military pilot equipment, such as helmets, visors, flight suits, and related equipment; and the use of semitransparent OPV devices to provide electricity for emergency power supply systems for pilots.

### BACKGROUND OF THE INVENTION

Modern military aircraft are very expensive and highly technologically advanced vehicles. The most important component of every military aircraft is the pilot, which represents an even larger investment, in term of the extensive training, than the vehicle. As such, the military puts particular emphasis on protecting their pilots and ensuring their recovery during an aircraft or flight emergency. In such a case, where the pilot must abandon “or punch-out of” the aircraft, the pilot's emergency transponder, emergency communication equipment, and other electronic devices are critical to ensure the pilots safety and eventual recovery.

If the recovery of a downed pilot is rapid, then a simple, short term power supply from a battery may suffice to power the emergency aircraft or communication electronics required by the pilot. If, however, the pilot can not be retrieved immediately, due to unfavorable conditions, time of battle, or hostile territorial regions, for example, then a battery of sufficient size to provide the portability necessary for ensuring the safety of a downed pilot may not be available or potentially may contribute too much mass, or take up too much valuable space, in the event the pilot must leave the aircraft to seek shelter. In this type situation, it would be desirable to provide the pilot with a means of producing additional electricity to ensure continued recharging of the small electronic, emergency, and communication systems necessary for operation and vital to the pilots survival.

### SUMMARY OF THE INVENTION

The present invention recognizes that, given the unknown conditions such a downed pilot might face, photovoltaics (PV) is an attractive potential electricity source, as sunlight is almost guaranteed to be present in any environment, at least some of the time. Traditional inorganic photovoltaic materials, such as crystalline silicon, are not practical given the size, weight, and bulkiness of such devices; and limited exposure to direct sunlight required for effective and efficient operation. Direct exposure to sunlight may jeopardize the pilots safety because that condition may require the pilot to seek refuge in an open field with little, or no, protection or area for the pilot to hide or remain concealed. OPV has a number of features that makes it potentially attractive for such an application, including low specific weight (W/g), flexibility, and thickness of the thin films. An important feature is the very low specific weight of OPV, as compared to other PV technologies, which could minimize additional weight for a downed pilot on the move. Additionally, OPV is inherently flexible, which potentially allows unique application methods for moving and non-planar surfaces, such as flight suits and curved helmets, respectively, and can also be semitransparent, for application to pilot visors. OPV produces electricity in low-light, shaded, and indirect-light conditions; and under natural sun light and artificial light conditions. These illuminating, or very low light conditions provide may provide an ideal environment for a pilot to produce electricity while remaining in a forest or thick brush condition, or even when in an abandoned building with, or without, operating overhead light fixtures.

The present invention recognizes that conventional pilot equipment, such as helmets, helmet visors, flight suits, and related equipment do not produce electricity necessary to help power emergency electronics or communication systems for downed pilots.

These problems and others are addressed by the present invention, a first exemplary embodiment of which comprises an OPV device, comprising one or more cells connected in series and/or parallel, applied as a film to conventional military pilot flight suits. In this embodiment, the OPV coating is applied as a completed device onto the fabric surface using a very thin, highly flexible substrate with pressure-sensitive adhesives, which is described in detail in Applicants' related applications. In such a fashion, the OPV device can be fabricated in a high-throughput manner via roll-to-roll, sheet-to-sheet, graveur, etc. coating methods for manufacturing onto a flexible planar substrate (with backing material, if necessary) that is then applied to both planar and curved fabric surfaces. The inherent flexibly of the OPV device ensures the film can be stretched to fit onto the flight suit fabric, and can withstand the bending, folding and creasing of the fabric without untoward damage to the OPV device. The OPV device can then be wired into the emergency electronics power supply system via wires, and any necessary power electronics, such as microinverters, lightweight batteries, etc. can also be integrated into the flight suit, along with the emergency electronic equipment. The top surface of the OPV device-coated suit may be covered in an additional layer to protect the OPV device from physical damage and environmental stress. In such a way, a pilot's flight suit may be turned into an electricity-generating surface to help power emergency electronic systems, while adding minimal weight for a downed pilot on the move. Furthermore, by selecting appropriate OPV material absorption properties, the surface visual effect of the flight suit may be chosen, while still generating power.

Another exemplary embodiment of the invention comprises a OPV device, comprising one or more cells connected in series and/or parallel, applied as a film to conventional military pilot flight helmets. In this example embodiment, the OPV coating is applied as a completed device onto the curved helmet surface using a very thin, highly flexible substrate with pressure-sensitive adhesives, which is described in detail in Applicants' related applications. The inherent flexibly of the OPV device ensures the film can be stretched to fit onto the flight suit helmet without untoward damage to the OPV device. Uniform, precision coating, such as needed for OPV devices, of such a highly curved surface as a military pilot helmet would be nearly impossible for conventional coating techniques. The OPV device can then be wired into the emergency electronics system and power supply system, including any necessary power electronics, such as microinverters, lightweight batteries, etc., all of which can be integrated into the pilot's flight suit or equipment.

A further exemplary embodiment of the invention comprises a semitransparent OPV device, comprising one or more cells connected in series and/or parallel, applied as a film to conventional military pilot helmet visors. In this embodiment, the semitransparent OPV coating is applied as a completed device onto the curved visor surface using a very thin, highly flexible substrate with pressure-sensitive adhesives, which is described in detail in Applicants' related applications. The unique properties of OPV ensures semitransparent devices can be fabricated that have: high visible light transmission (VLT), low weight, reasonable power conversion efficiencies, and tunable absorption properties to allow fabrication of a pilots helmet visor with vision-enhancing transmission characteristics. Furthermore, the inherent flexibly of the OPV device ensures the film can be stretched to fit onto the visor without untoward damage to the OPV device. Uniform, precision coating, such as needed for OPV devices, of curved surfaces such as military pilot helmet visors would be challenging for conventional coating techniques. The OPV device can be wired through the helmet, which may also be an electricity-generating surface, into the emergency electronics system and power supply system, including any necessary power electronics, such as microinverters, lightweight batteries, etc., all of which can be integrated into the pilot's flight suit.

Other features and advantages of the present invention will become apparent to those skilled in the art upon review of the following detailed description and drawings.

### BRIEF DESCRIPTION OF THE DRAWINGS

These and other aspects and features of embodiments of the present invention will be better understood after a reading of the following detailed description, together with the attached drawings, wherein:

FIG. 1 is a cross-sectional view of a pressure-sensitive adhesive-coated organic photovoltaic device, itself coated on a thin flexible substrate with a transfer release layer and rigid backing layer, which can be used to laminate organic photovoltaic devices onto planar and curved military pilot equipment according to an exemplary embodiment of this invention.

FIG. 2 is a cross-sectional view of an organic photovoltaic device coated onto a planar military pilot flight suit material using the pressure-sensitive adhesive method according to an exemplary embodiment of the invention.

FIG. 3 is a cross-sectional view of an organic photovoltaic device coated onto a curved military pilot helmet surface using the pressure-sensitive adhesive method according to an exemplary embodiment of the invention.

FIG. 4 is a cross-sectional view of a semitransparent organic photovoltaic device coated onto a curved military pilot helmet visor using the pressure-sensitive adhesive method according to an exemplary embodiment of the invention.

### DETAILED DESCRIPTION OF THE EXEMPLARY EMBODIMENTS OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

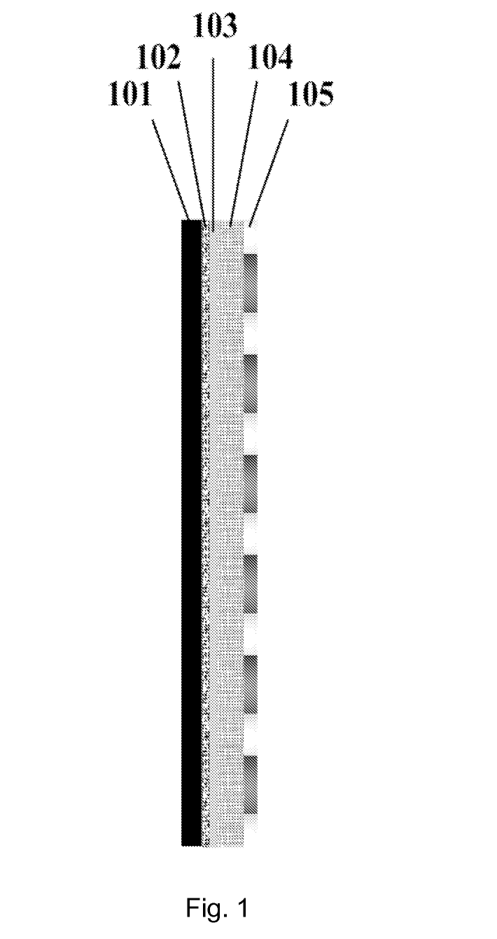

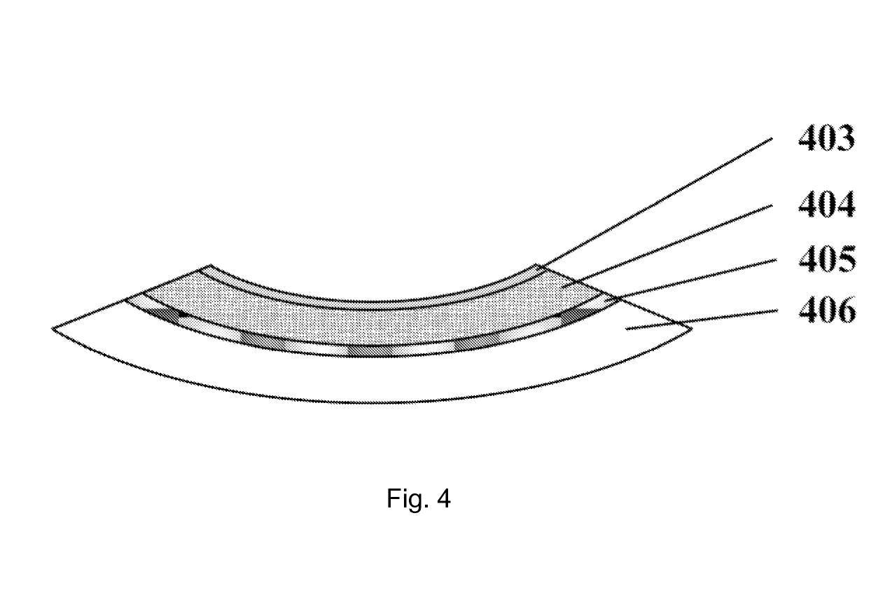

Referring now to the drawings, FIGS. 1-4 illustrate exemplary embodiments of electricity-generating coatings for military pilot equipment, including opaque (FIGS. 1-3) and semitransparent (FIG. 4) applications.

Referring to FIG. 1, which provides a cross-sectional view of an intermediate film stack produced for the eventual fabrication of electricity-generating coatings for military pilot equipment, the film is prepared upon a temporary base layer 101, in order to provide sufficient rigidity to allow conventional manufacturing techniques, including high-speed roll-to-roll, sheet-to-sheet, graveur, etc. coating methods for manufacturing. The base layer can include thick polymer foils, metal foils, or any convenient substrate material, depending on the chosen manufacturing methods. On top of the base layer is a transfer release layer 102 that allows easy removal of the base layer and transfer layer from the thin flexible substrate 103, which are all laminated together as known to those skilled in the art. The thin flexible substrate is any appropriate substrate material that is highly flexible and transparent, such as very thin polymer foils, including but not limited to polyethyleneterephthalate (PET). On top of this is coated an OPV device, comprising one or more cells connected in series and/or parallel, which is inherently flexible and thus contains no highly crystalline materials. The multi-layered OPV device is coated and processed according to standard methods known to those skilled in the art, such as slot-die coating and laser scribing, which are compatible with high-throughput manufacturing techniques, including high-speed roll-to-roll, sheet-to-sheet, graveur, etc. coating methods for manufacturing. Finally, the OPV device is coated on top with a transparent pressure-sensitive adhesive according to methods know to those skilled in the art. The resulting film comprising layers 101-105 can be used to transfer the OPV device comprising layers 103-105 onto military pilot equipment to convert them into electricity-generating surfaces to generate power for emergency equipment.

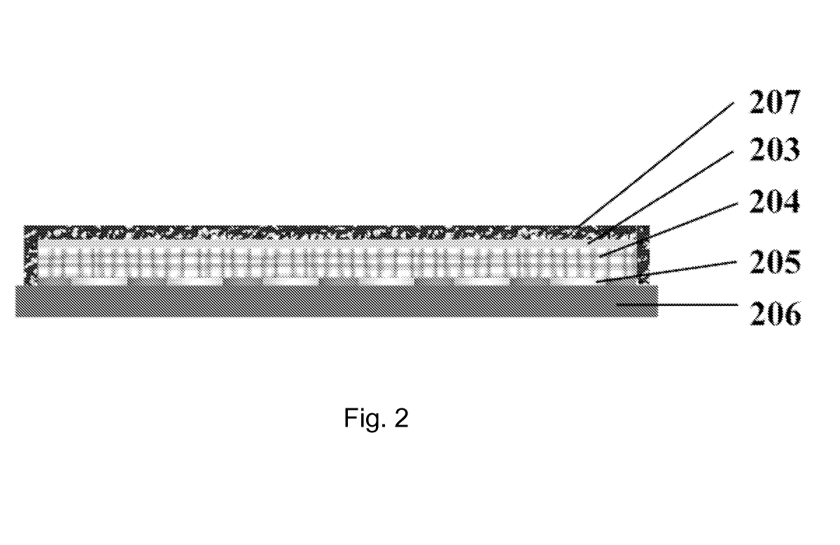

Referring to FIG. 2, which provides a cross-sectional view of an electricity-generating military pilot flight suit surface produced via the pressure-sensitive adhesive method, the base layer 206 includes a conventional military pilot slight suit. Coated onto the flight suit fabric using lamination, stretching, and press-forming, with or without vacuum assistance in removing entrained air, is the electricity-generating OPV device 204, which is adhered to the fabric using the pressure-sensitive adhesive layer 205, and is supported by the thin flexible substrate layer 203. Finally, the whole OPV device may be protected via a top encapsulant layer 207. Not shown are any wires or any power circuitry (e.g. microinverters, combiner circuits, etc.), if required, which could be integrated into a portion of the flight suit.

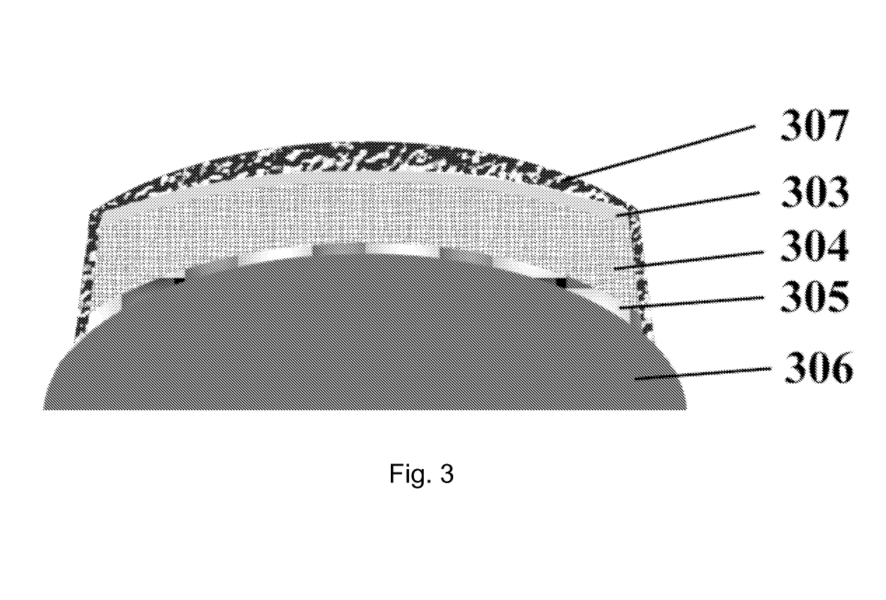

Referring to FIG. 3, which provides a cross-sectional view of a curved electricity-generating military pilot helmet surface produced via the pressure-sensitive adhesive method, the base layer 306 includes a conventional military pilot helmet. Coated onto the helmet panel using lamination, stretching, and press-forming, with or without vacuum assistance in removing entrained air, is the electricity-generating OPV device 304, which is adhered to the helmet using the pressure-sensitive adhesive layer 305, and is supported by the thin flexible substrate layer 303. Finally, the whole OPV device may be protected via a clear hard-coat encapsulant 307 (e.g. a clear epoxy), due to the stresses helmets are subjected to. The unique and inherent flexibility of OPV devices allows lamination onto curved surfaces without significant disruption of device performance, and enables production of three-dimensional OPV devices that would be difficult to produce via conventional coating techniques due to realities of capillarity flow on curved surfaces. This method enables OPV devices to be laminated onto surfaces of arbitrary and changing curvature, which would be impossible via conventional solution coating techniques. While, in this exemplary embodiment, the method is necessarily a discrete object process for the fabrication of each individual helmet, the intermediate transfer film (see FIG. 1) used to transfer the completed OPV device onto the panel can be produced in a continuous, high-throughput methodology. Not shown are any wires or power circuitry (e.g. microinverters, combiner circuits, etc.), if required, which could be integrated into a portion of the flight suit.

Referring to FIG. 4, which provides a cross-sectional view of a curved electricity-generating military pilot helmet visor surface produced via the pressure-sensitive adhesive method, the base layer 406 includes a conventional curved military pilot helmet visor. Coated onto the visor using lamination, stretching, and press-forming, with or without vacuum assistance in removing entrained air, is the electricity-generating semitransparent OPV device 404, which is adhered to the window using the pressure-sensitive adhesive layer 405, and is supported by the thin flexible substrate layer 403. The unique properties of OPV ensures semitransparent devices can be fabricated that have: high visible light transmission (VLT), low weight, reasonable power conversion efficiencies, and tunable absorption properties to allow fabrication of visors with vision-enhancing transmission characteristics. Furthermore, the inherent flexibly of the OPV device ensures the film can be stretched to fit onto the visor without untoward damage to the OPV device. Not shown are any wires or power circuitry (e.g. microinverters, combiner circuits, etc.), if required, which could be integrated into a portion of the flight suit, or any protective coatings that might be desirable.

The present invention has been described herein in terms of several preferred embodiments. However, modifications and additions to these embodiments will become apparent to those of ordinary skill in the art upon a reading of the foregoing description. It is intended that all such modifications and additions comprise a part of the present invention to the extent that they fall within the scope of the several claims appended hereto.

What is claimed is:

1. An electricity-generating coating for military pilot equipment comprising:
a conformal organic photovoltaic device, including one or more cells connected in series and/or parallel,
adhered to pilot equipment surfaces,
along with the wires and power electronics to allow such coatings to provide electricity for pilot emergency electronic equipment.

2. The electricity-generating coating of claim 1, wherein the organic photovoltaic device is adhered to the military aircraft window surfaces using a pressure-sensitive adhesive.

3. The electricity-generating coating of claim 2, wherein the organic photovoltaic device is covered by a very thin, highly flexible transparent substrate, such as polyethylene terephthalate (PET).

4. The electricity-generating coating of claim 3, wherein the organic photovoltaic device is protected by a transparent encapsulant material.

5. The electricity-generating coating of claim 4, wherein the military pilot equipment is a flight suit.

6. The electricity-generating coating of claim 4, wherein the military pilot equipment is a helmet.

7. The electricity-generating coating of claim 4, wherein:
the military pilot equipment is a helmet visor, and
the organic photovoltaic device is semitransparent.

8. A transfer film comprising:
a support substrate,
a transfer release layer laminated between the support substrate and a very thin, highly flexible transparent substrate, such as PET,
an organic photovoltaic device, comprising one or more cells connected in series and/or parallel,
and a pressure-sensitive adhesive.

9. The transfer film of claim 8, wherein the support substrate is a rigid material such as glass, plastic, or thick metal.

10. The transfer film of claim 8, wherein the support substrate is a flexible material, such as a polymer or metal foil compatible with roll-to-roll, sheet-to-sheet, graveur, etc. coating methods for manufacturing.

11. The transfer film of claim 8, wherein the organic photovoltaic device is semitransparent.

12. A method for the manufacture of the flexible transfer film of claim 8, wherein:
the flexible foil is coated with the transfer release material,
laminated with the very thin, highly flexible transparent substrate, such as PET,
coated with the multilayer organic photovoltaic device,
and coated with a pressure-sensitive adhesive,
all in a roll-to-roll, sheet-to-sheet, graveur, etc. coating methods for manufacturing manner,
and utilizing solution-processing,
to allow low-cost, high-throughput manufacturing.

13. A method for the fabrication of the electricity-generating coating of claim 3, wherein:
the transfer film of claim 8 is applied to the military pilot equipment in such a way as to adhere the pressure-sensitive adhesive to the equipment surface,
lamination, stretching, press-forming, and/or vacuum removal of air entrainment are utilized to ensure conformal adhesion,
the backing substrate and transfer release layer are removed.

14. A method for the fabrication of the electricity-generating coating of claim 6, wherein:
the transfer film of claim 8 is applied to a curved military helmet in such a way as to adhere the pressure-sensitive adhesive to the helmet surface,
lamination, stretching, press-forming, and/or vacuum removal of air entrainment are utilized to ensure conformal adhesion,
the backing substrate and transfer release layer are removed.

15. A method for the fabrication of the electricity-generating coating of claim 7, wherein:
the transfer film of claim 11 is applied to a curved military helmet visor in such a way as to adhere the pressure-sensitive adhesive to the visor surface,
lamination, stretching, press-forming, and/or vacuum removal of air entrainment are utilized to ensure conformal adhesion,
the backing substrate and transfer release layer are removed.
